(19) United States
(12) Patent Application Publication
(10) Pub. No.: US 2003/0032212 A1
(43) Pub. Date: Feb. 13, 2003

(54) LED focusing cup in a stacked substrate

(76) Inventors: Bily Wang, Hsin-Chu (TW); Bill Chang, Hsin-Chu (TW); Yann Lee, Hsin-Chu (TW)

Correspondence Address: Hung Chang Lin, 8 Schindler Court, Silver Spring, MD, 20903, US

(21) Appl. No.: 09/922,688

(22) Filed: Aug. 7, 2001

(51) Int. Cl. H01L 21/00

(52) U.S. Cl. 438/48

(57) ABSTRACT

An optoelectronic device is placed in a through hole of an upper substrate and mounted on a lower substrate, which is stacked under the upper substrate. The through hole forms a focusing cup for the optoelectronic device. A metallic base plate can be inserted between the optoelectronic device and the lower substrate to enhance light reflection and heat removal. The through hole can be lined with metallic coating to enhance light reflection.

### BACKGROUND OF THE INVENTION

(1) Field of the Invention

The invention relates to light emitting diodes (LED), particularly the structure of the focusing cup for the LED.

(2) Brief Description of Related Art

In optoelectronic devices such as the LED, laser diode, photo diode, image sensor, etc., the device chip is packaged in a recess to reflect light. FIG. 1 shows a prior art package. A LED 10 is mounted in a recess 14 in one of the leads 11. The top electrode of the LED 10 is wire-bonded by wire 13 to a second lead 12. The structure is then sealed in a package 15.

In a copending U.S. patent application Ser. No. 09/731,223, filed Dec. 7, 2000, a focusing cup is cast around the LED to focus the light. The structure requires casting a cup over a substrate to surround the LED for focusing the light.

### SUMMARY OF THE INVENTION

An object of this invention is to focus an optoelectronic device without using a special recess lead structure. Another object of this invention is to mount an optoelectronic device on a substrate without requiring a special process for casting a focusing cup.

These objects are achieved by stacking two substrates, The upper substrate has a through hole to surround the optoelectronic device. The wall of the through hole can be coated with light reflecting material and be shaped to optimize focusing. A bottom metallic metal plate can be placed under the optoelectronic to enhance heat removal and light reflection. The through hole can be lined with metallic coating to enhance light reflection

### BRIEF DESCRIPTION OF THE SEVERAL VIEWS OF THE DRAWINGS

FIG. 1 shows a prior art package of a LED having a focusing cup on top of one of the leads.

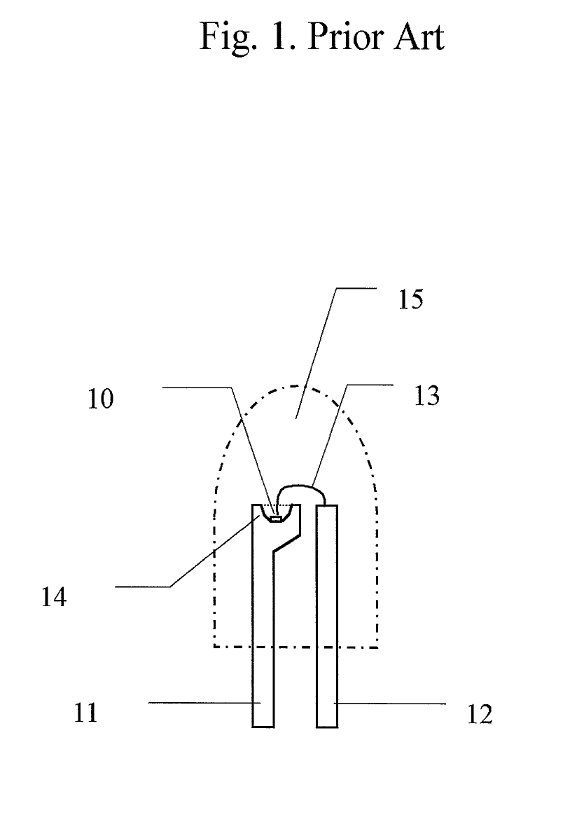

FIG. 2 shows the basic stacked substrate structure with a through hole of the present invention.

FIG. 3 shows an optoelectronic device mounted inside the through hole.

FIG. 4 shows a conical through hole with a wider base.

FIG. 5 shows a cylindrical through hole.

FIG. 6 shows an optoelectronic device mounted inside cylindrical through hole.

FIG. 7 shows an optoelectronic device mounted on a metal base plate over the lower substrate.

FIG. 8 shows folded base plates.

FIG. 9 shows metallic lining of the through hole.

FIG. 10 shows an optoelectronic device mounted on a metallic base plate in a through hole with metallic lining

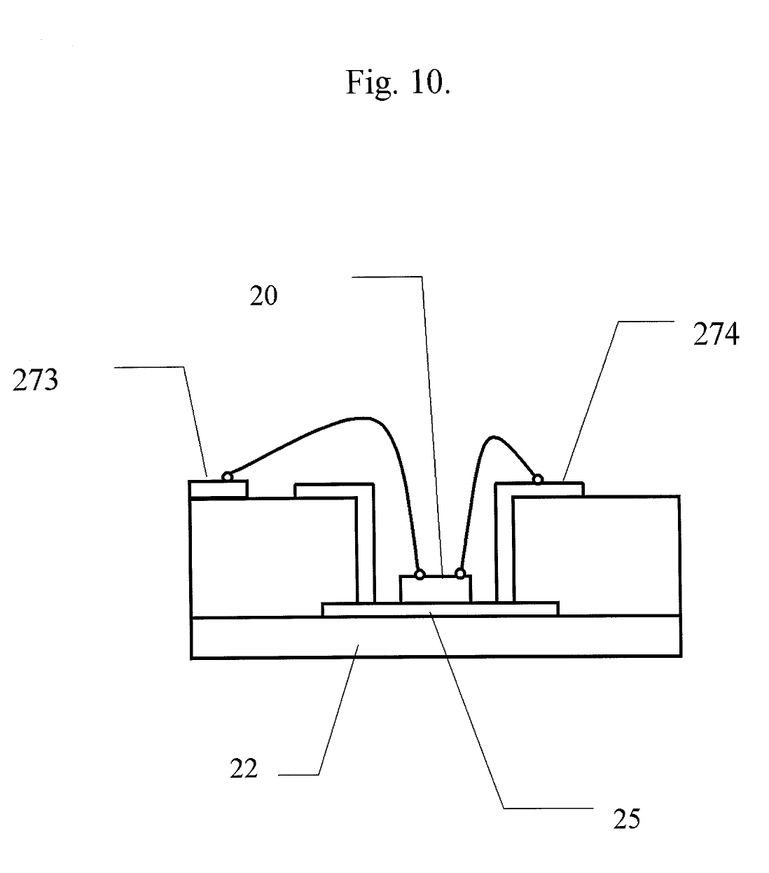

FIG. 11 shows folded base plates together with metallic linings of the through hole.

FIG. 12 shows the extension of the metal base plate to the bottom of the lower substrate for surface mounting.

FIG. 13 shows the addition of metallic lining in the through hole of the of FIG. 12.

### DETAILED DESCRIPTION OF THE INVENTION

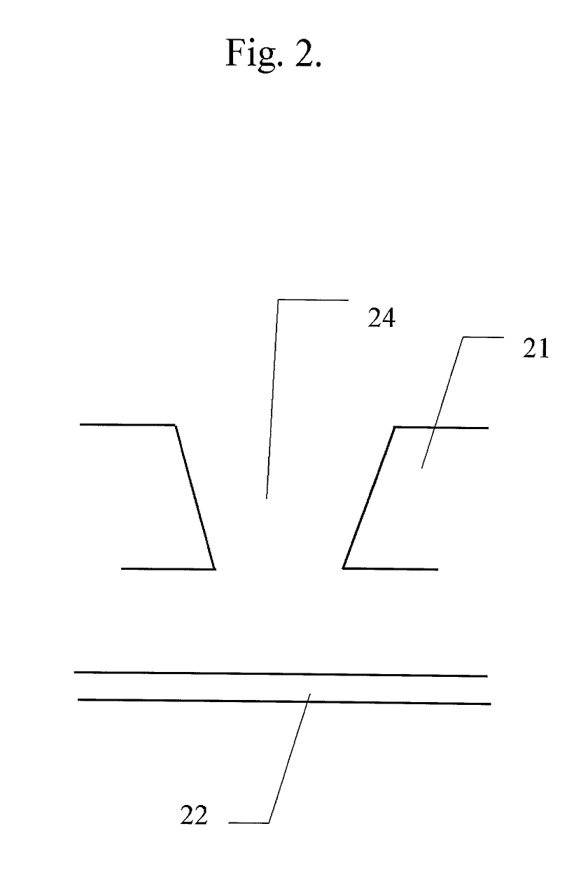

FIG. 2 shows the basic structure of the present invention. Two substrates 21 and 22 are stacked. The upper substrate has a through hole 24 for enclosing an optoelectronic device.

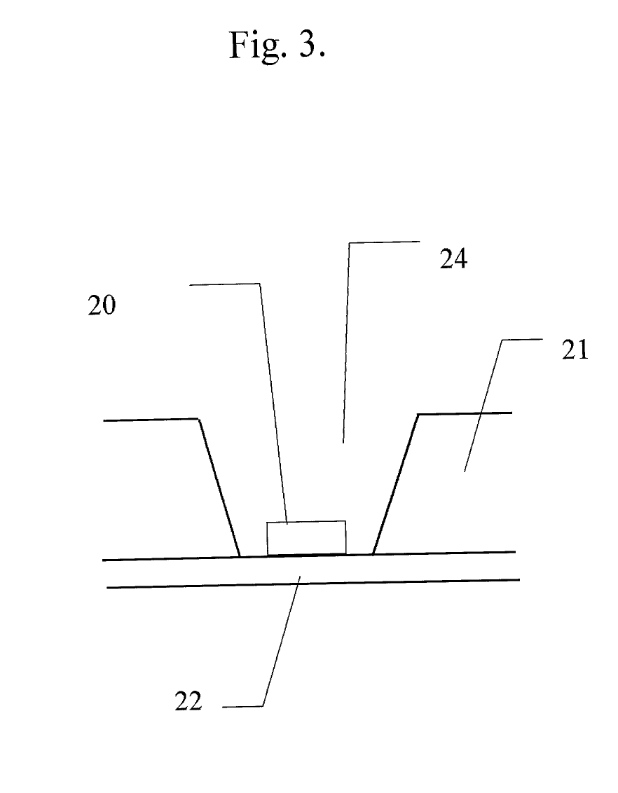

FIG. 3 a shows a conical through hole 24 with a narrower base in the upper substrate 21. The optoelectronic device 20 is mounted on the lower substrate 22 inside the through hole 24.

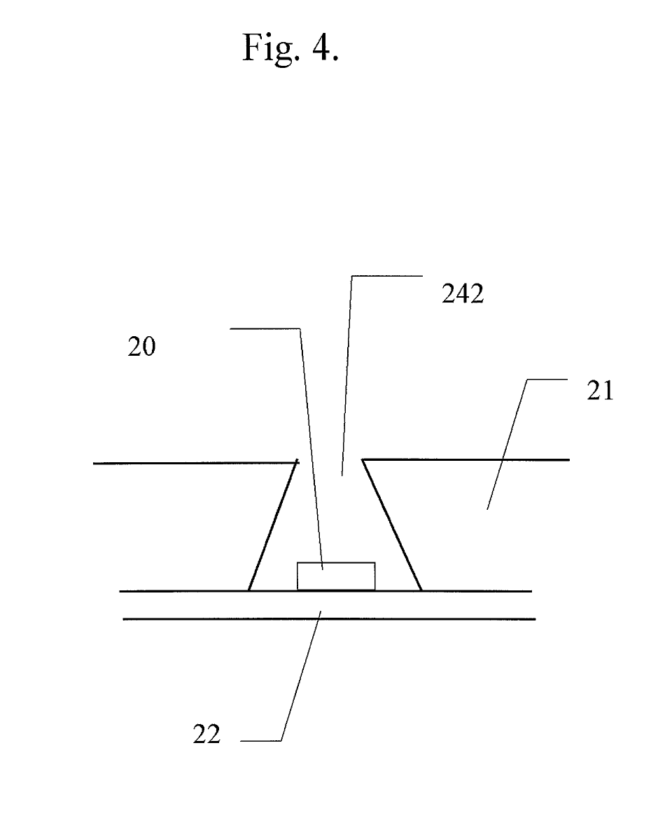

FIG. 4 shows a conical through hole 242 with a wider base in the upper substrate 21. The optoelectronic device 20 is mounted on the lower substrate 22 inside the through hole 242.

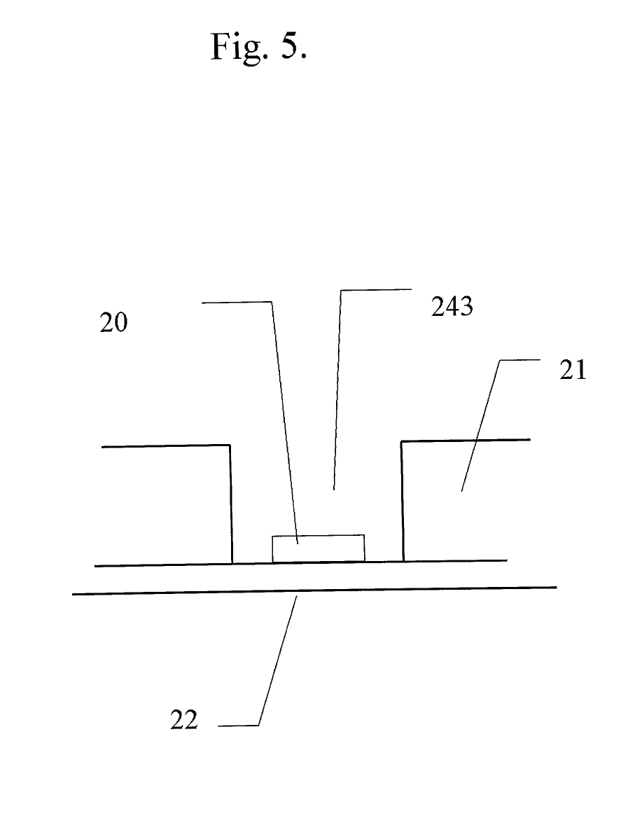

FIG. 5 shows a cylindrical through hole 243 in the upper substrate 21. The optoelectronic device 20 is mounted on the lower substrate 22 inside the through hole 243.

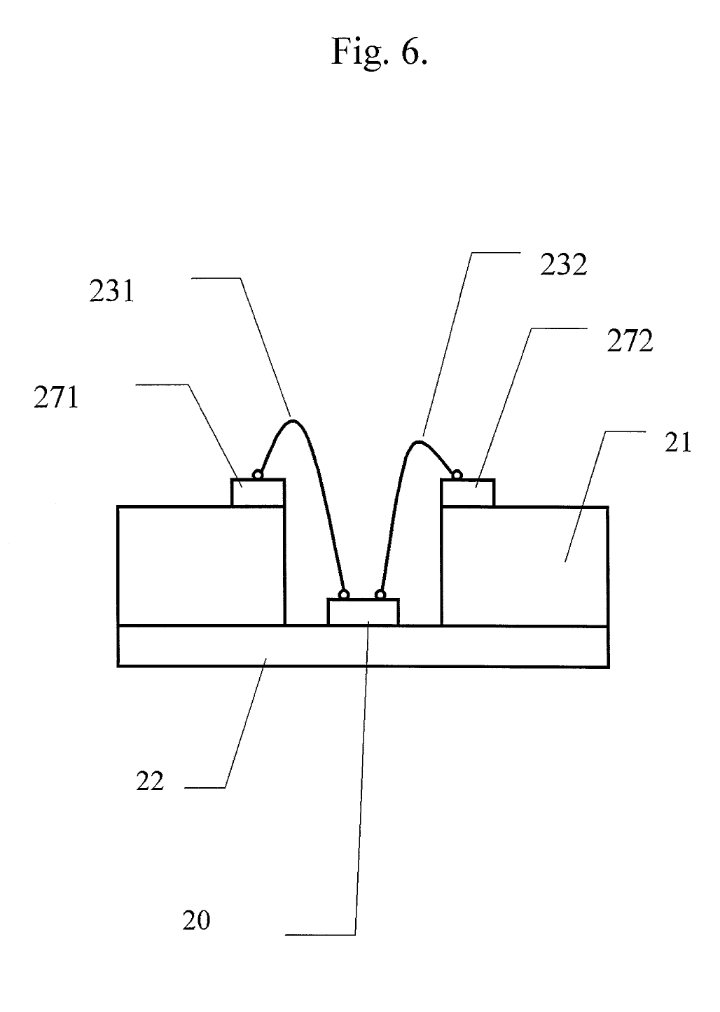

FIG. 6 shows an optoelectronic device 20 mounted on the lower substrate 22 inside the through hole of the upper substrate 21. The optoelectric device 20 has two top electrodes, which are wire bonded by wires 231 and 232 to two boding pads 271, 272 respectively on top of the upper substrate 21.

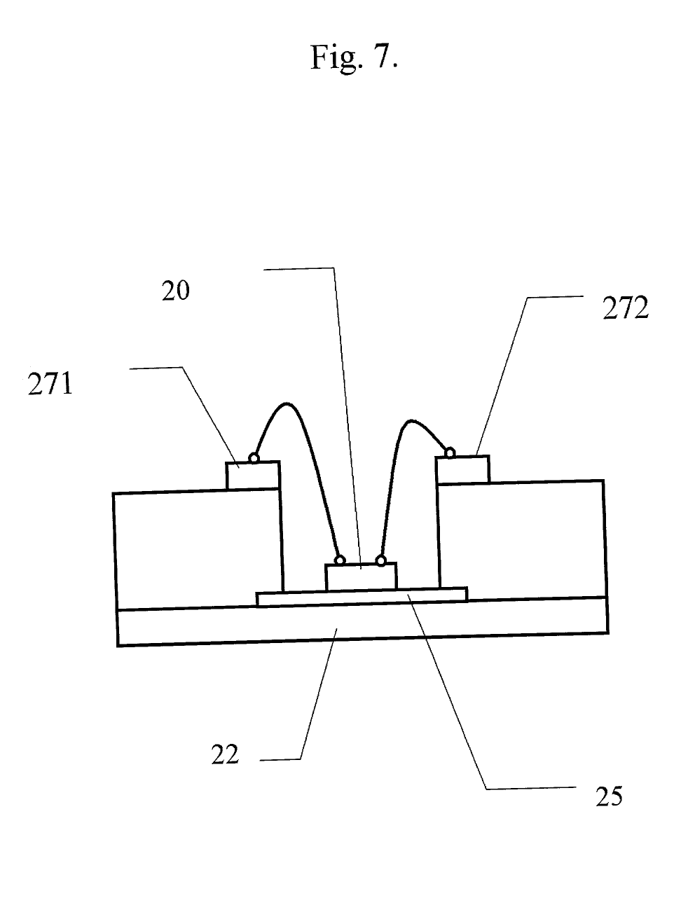

FIG. 7 shows the addition of a metallic base plate 25 between the optoelectronic device 20 and the lower substrate 22 in the structure shown in FIG. 6. The function of the metallic base plate 25 is to increase the reflectivity of the optoelectronic device 20.

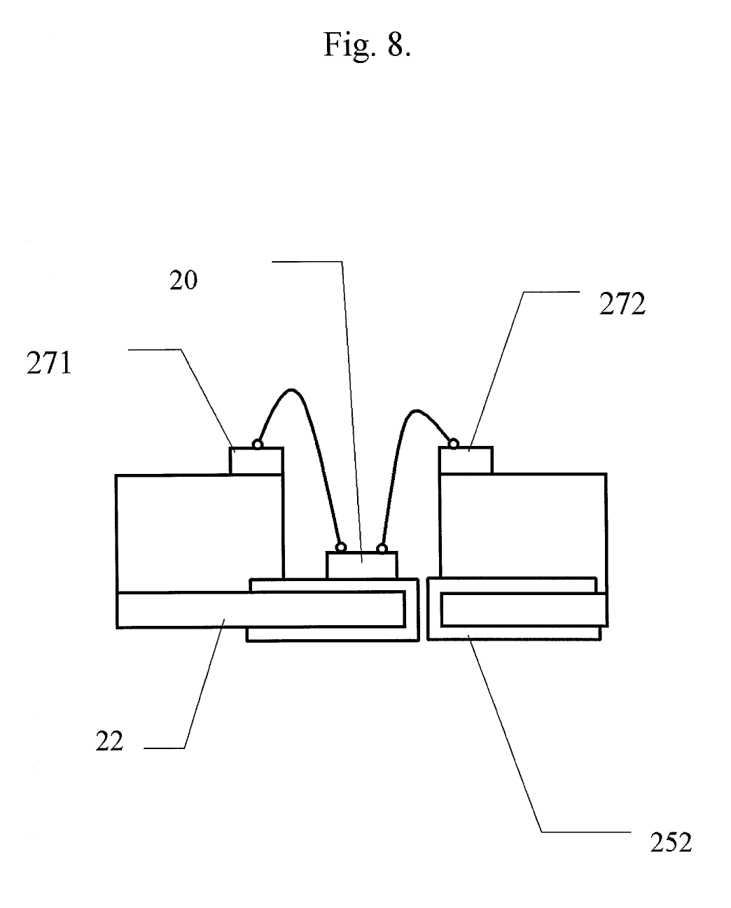

FIG. 8 shows the base plate of FIG. 7 being folded to the bottom of the lower substrate 22 as an extension 252. Such a folded extension serves a heat sink for the optoelectronic device 20.

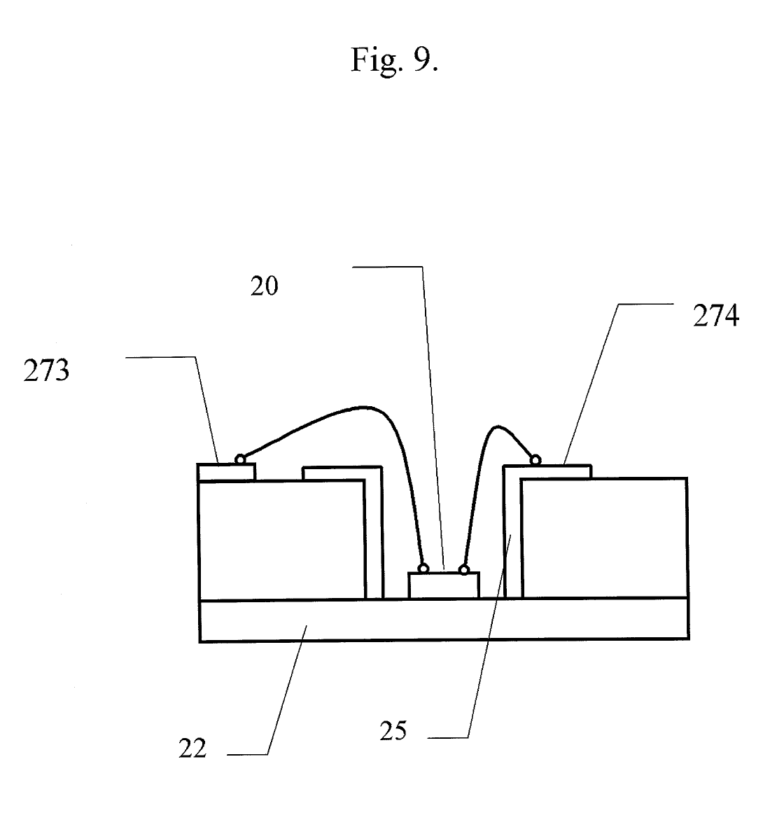

FIG. 9 shows the through hole in the upper through hole has metallic lining 25 to increase reflectivity of the optoelectronic device 20.

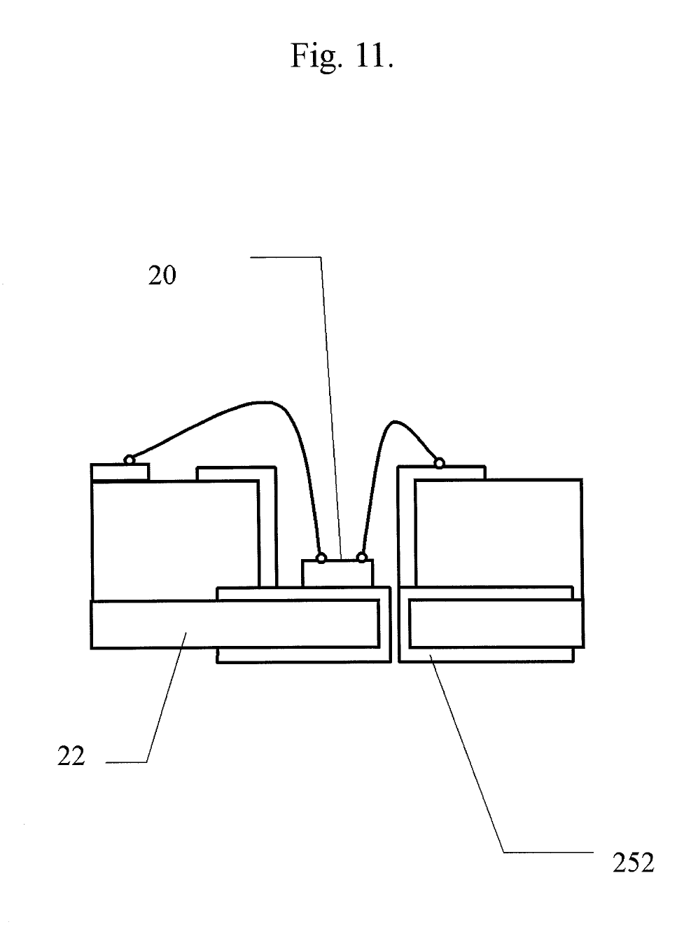

FIG. 11 shows the addition of a base plate 252 and the metallic lining of the through hole to increase reflectivity.

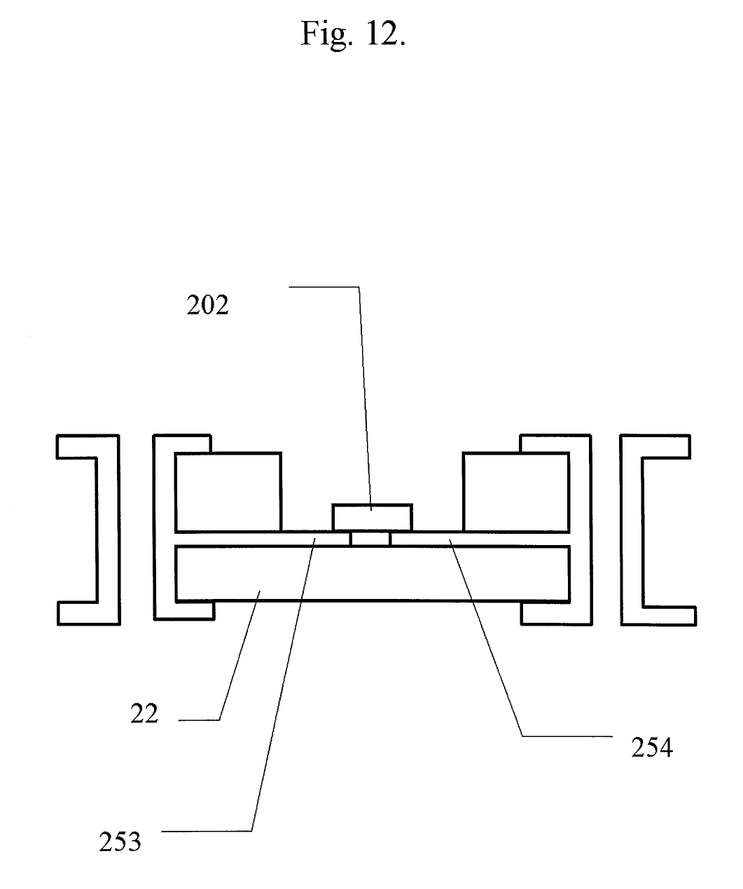

FIG. 12 shows two folded base plates, 253, 254 each coupled to one electrode of the electrodes of the optoelectronic device 202.

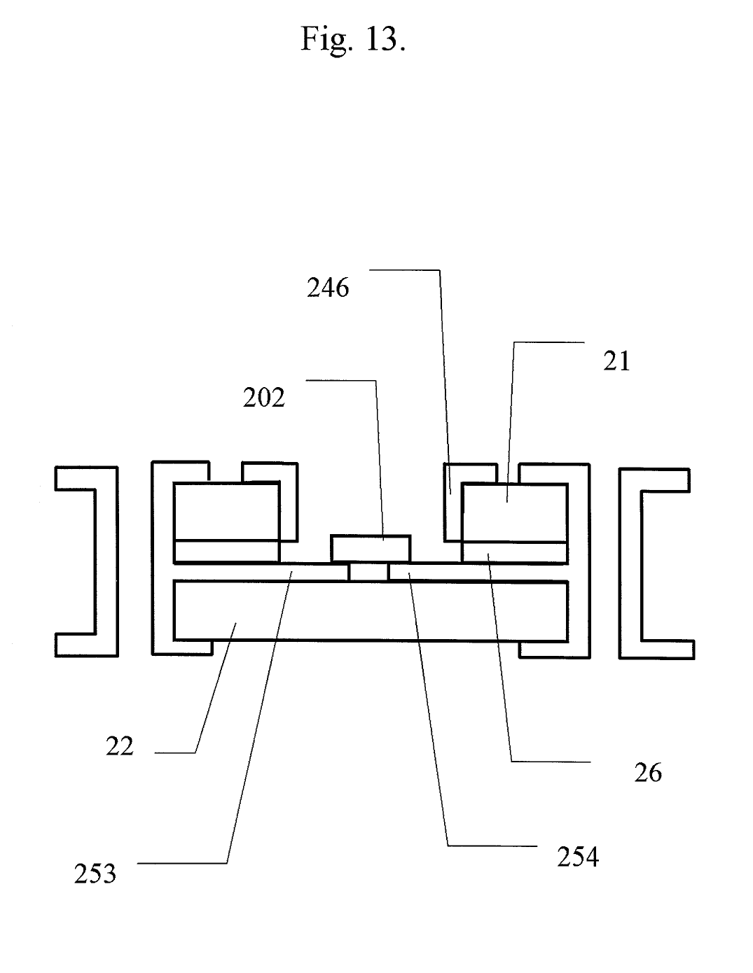

FIG. 13 shows the addition of metallic lining 246 on the wall of the through hole to the double folded base plate structure of FIG. 12. An insulation material 26 is inserted between 21 and 22 to isolate the metal 246 and 254 and to avoid metal circuits shorting.

While the preferred embodiments of this invention have been described, it will be apparent to those skilled in the art that various modifications may be made in the embodiments without departing from the spirit of the present invention. Such modifications are all within the scope of this invention.

1. A method for fabricating a focusing cup for an optoelectronic device package comprising the steps of:
forming a through hole in an upper insulating substrate;
stacking said upper insulating substrate over a lower insulating substrate; and
mounting an optoelectronic device on said lower substrate inside said through hole.

2. The method as described in claim 1, wherein said through hole is of conical shape.

3. The method as described in claim 2, wherein said through hole has larger top than a smaller bottom.

4. The method as described in claim 2, wherein said through hole has a smaller top and a larger bottom.

5. The method as described in claim 1, wherein said through hole is of cylindrical shape.

6. The method as described in claim 1, wherein said optoelectronic device has two top electrodes wire-bonded respectively to two bonding pads mounted on top of said upper substrate.

7. The method as described in claim 1, further comprising a step of inserting a metallic plate between said optoelectronic device and said lower substrate to enhance light reflection.

8. The method as described in claim 7, wherein said metallic plate is folded to the bottom of said lower substrate to enhance heat removal.

9. The method as described in claim 1, further comprising the step of lining the wall of said through hole with metal coating to enhance light reflection.

10. The method as described in claim 7, further comprising a step of lining the wall of said through hole with metal coating to enhance light reflection.

11. The method as described in claim 8, further comprising a step of lining the wall of said through hole with metal coating to enhance light reflection.

12. The method as described in claim 1, wherein said optoelectronic device has two bottom electrodes, each bonded to a metallic plate to enhance light reflection and folded to the bottom of said lower substrate to enhance heat removal.

13. A package for optoelectronic device comprising:
an upper insulating substrate;
a lower insulating substrate;
a through hole in said upper insulating substrate;
an optoelectronic device mounted on said lower substrate and inside said through hole.

14. The package as described in claim 13, further comprising a metallic base plate inserted between said optoelectronic device and said lower substrate to enhance light reflection.

15. The package as described in claim 14, wherein said metallic base plate is folded over the lower substrate to enhance heat removal.

16. The package as described in claim 13, further comprising metal lining coated over the wall of said through hole to enhance light reflection.

17. The package as described in claim 13, further comprising at least two metallic base plates inserted between said optoelectronic device and said lower substrate to enhance light reflection.

18. The package as described in claim 17, wherein said optoelectronic device has two bottom electrodes each coupled to one of said metallic base plate.
